(19) United States
(12) Patent Application Publication
(10) Pub. No.: US 2024/0112941 A1
(43) Pub. Date: Apr. 4, 2024

(54) METHOD FOR MANUFACTURING ELECTRONIC COMPONENT DEVICE AND ELECTRONIC COMPONENT DEVICE

(71) Applicant: Showa Denko Materials Co., Ltd., Tokyo (JP)

(72) Inventors: Masaaki TAKEKOSHI, Tokyo (JP); Keisuke NISHIDO, Tokyo (JP)

(21) Appl. No.: 17/768,746

(22) PCT Filed: Oct. 17, 2019
(86) PCT No.: PCT/JP2019/040991

§ 371 Date: Apr. 13, 2022

(51) Int. Cl. H01L 21/683; H01L 21/48; H01L 21/56; H01L 23/00; H01L 23/31; H01L 23/498; H01L 25/16

(52) U.S. Cl. CPC H01L 21/6835; H01L 21/4857; H01L 21/565; H01L 23/3142; H01L 23/49822; H01L 24/08; H01L 24/80; H01L 25/16; H01L 2221/68331; H01L 2221/68386; H01L 2224/08225; H01L 2224/80895; H01L 2924/19105

(57) ABSTRACT

Disclosed is a method for manufacturing an electronic component device, the method including, in the stated order: a step of disposing an IC chip and a chip-type passive component on a temporary fixing material layer of a carrier substrate, the passive component having a main body part and a connection part provided on an outer surface of the main body part, the connection part being interposed between the main body part and the temporary fixing material layer to form a gap between the main body part and the temporary fixing material layer; a step of forming a sealing layer sealing the IC chip and the passive component on the temporary fixing material layer by a sealing material containing a curable resin and a filler; a step of curing the sealing layer to form a sealed structure; and a step of peeling off the carrier substrate from the sealed structure. When a top cut particle diameter of the filler is designated as D and a width of the gap between the main body part and the temporary fixing material layer is designated as G, D/G is 1.5 or less.

### TECHNICAL FIELD

The present invention relates to a method for manufacturing an electronic component device and an electronic component device.

### BACKGROUND ART

As a method for manufacturing a semiconductor package having a plurality of semiconductor chips, a method has been known in which semiconductor chips (dies) are disposed on a temporary adhesive layer that is provided on a carrier substrate, the semiconductor chips are sealed, and then the carrier substrate is peeled off (for example, Patent Literature 1).

### CITATION LIST

### Patent Literature

Patent Literature 1: International Publication WO 2017/057355

### SUMMARY OF INVENTION

### Technical Problem

It is expected that a composite electronic component device having an IC chip and a passive component can also be efficiently manufactured by a method of forming a sealing layer in a state where those component parts are temporarily fixed onto a temporary fixing material layer such as a temporary adhesive layer and then peeling off the temporary fixing material layer.

However, there is a problem of so-called die shift that the IC chip moves from a predetermined position during the step of forming a sealing layer. In addition, there is a tendency that the passive component is also likely to move from a predetermined position during the step of forming a sealing layer, in association with miniaturization.

In this regard, an aspect of the present invention provides a method of suppressing the movement of a passive component in association with the formation of a sealing layer in the manufacturing of an electronic component device having an IC chip, a passive component, and a sealing layer sealing these component parts. Another aspect of the present invention provides an electronic component device which has an IC chip, a passive component, and a sealing layer sealing these component parts and can be manufactured while suppressing the movement of the passive component in association with the formation of the sealing layer.

### Solution to Problem

An aspect of the present invention provides a method for manufacturing an electronic component device. The method according to the aspect of the present invention includes, in the stated order:
a step of preparing a carrier substrate comprising a support and a temporary fixing material layer provided on the support;
a step of disposing an IC chip and a chip-type passive component on the temporary fixing material layer, the passive component having a main body part and a connection part provided on an outer surface of the main body part, the connection part being interposed between the main body part and the temporary fixing material layer to form a gap between the main body part and the temporary fixing material layer;
a step of forming a sealing layer sealing the IC chip and the passive component on the temporary fixing material layer by a sealing material containing a curable resin and a filler;
a step of curing the sealing layer to form a sealed structure having the passive component, the IC chip, and the cured sealing layer; and
a step of peeling off the carrier substrate from the sealed structure.

When a top cut particle diameter of the filler is designated as D and a width of the gap between the main body part and the temporary fixing material layer is designated as G, D/G is 1.5 or less.

Another aspect of the present invention provides an electronic component device including:
a sealed structure having an IC chip, a chip-type passive component, and a sealing layer sealing the IC chip and the passive component; and
a redistribution layer provided on one main surface side of the sealed structure.

The passive component has a main body part and a connection part provided on an outer surface of the main body part, and the redistribution layer has a wiring connected to the connection part. The passive component has a main body part and a connection part provided on an outer surface of the main body part, and the connection part is interposed between the main body part and the redistribution layer to form a gap between the main body part and the redistribution layer. The sealing layer is a cured product of a sealing material containing a curable resin and a filler. When a top cut particle diameter of a particle diameter of the filler is designated as D and a width of the gap between the main body part and the redistribution layer is designated as G, D/G is 1.5 or less.

### Advantageous Effects of Invention

According to an aspect of the present invention, it is possible to suppress the movement of a passive component in association with the formation of a sealing layer in the manufacturing of an electronic component device having an IC chip, a passive component, and a sealing layer sealing these component parts.

### BRIEF DESCRIPTION OF DRAWINGS

FIG. 1 is a process diagram illustrating an embodiment of a method for manufacturing an electronic component device.

FIG. 2 is a process diagram illustrating an embodiment of the method for manufacturing an electronic component device.

FIG. 3 is a cross-sectional view illustrating an embodiment of a passive component and a temporary fixing material layer.

FIG. 4 is a micrograph showing an example of a state where a passive component moves from a predetermined position.

### DESCRIPTION OF EMBODIMENTS

Hereinafter, some embodiments of the present invention will be specifically described. However, the present invention is not limited to the following embodiments.

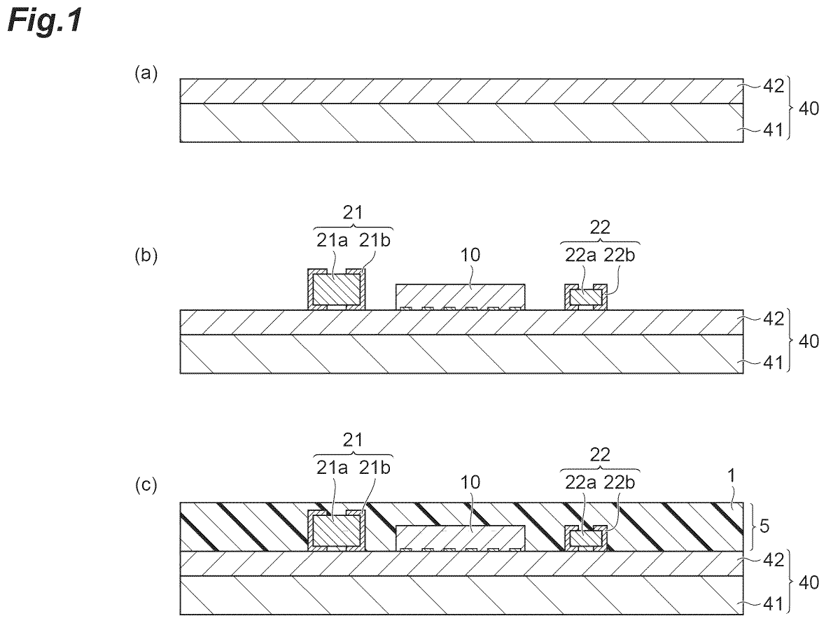

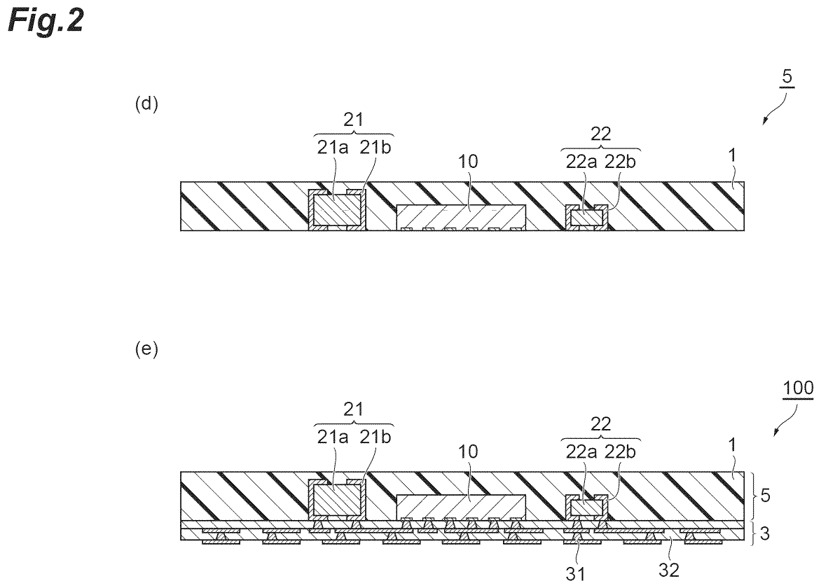

FIG. 1 and FIG. 2 are process diagrams illustrating embodiments of a method for manufacturing an electronic component device. The method according to the embodiments illustrated in FIG. 1 and FIG. 2 includes, in the stated order: a step of preparing a carrier substrate 40 including a support 41 and a temporary fixing material layer 42 provided on the support 41 (FIG. 1(a)); a step of disposing an IC chip 10 and chip-type passive components 21 and 22 on the temporary fixing material layer 42 (FIG. 1(b)); a step of forming a sealing layer 1 sealing the IC chip 10 and the passive components 21 and 22 on the temporary fixing material layer 42 by a sealing material containing a curable resin and a filler (FIG. 1(c)); a step of curing the sealing layer 1 to form a sealed structure 5 having the IC chip 10, the passive components 21 and 22, and the cured sealing layer 1 (a cured product of the sealing material) (FIG. 1(c)); a step of peeling off the carrier substrate 40 from the sealed structure 5 (FIG. 2(d)); and a step of forming a redistribution layer 3 having a wiring 31 and an insulating layer 32 on one main surface side of the sealed structure 5.

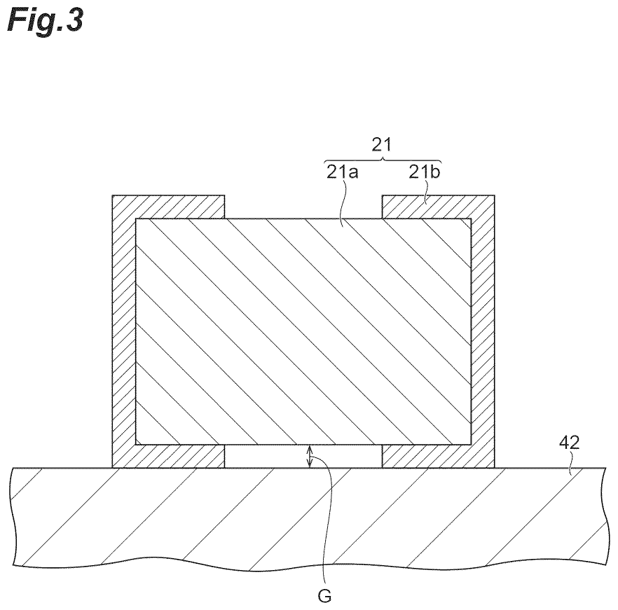

The passive components 21 and 22 have main body parts 21a and 22a and connection parts 21b and 22b provided on outer surfaces of the main body parts 21a and 22a, and the connection parts 21b and 22b are interposed between the main body parts 21a and 22a and the temporary fixing material layer 42 to form gaps between the main body parts 21a and 22a and the temporary fixing material layer 42. FIG. 3 is a cross-sectional view illustrating an example of a state where the passive component 21 is temporarily fixed onto the temporary fixing material layer. The connection part 21b is interposed between the main body part 21a of the passive component 21 and the temporary fixing material layer 42 to form a gap having a width G.

The carrier substrate 40 can be obtained by forming the temporary fixing material layer 42 on the support 41. The temporary fixing material layer 42 having a film shape may be stacked on the support 41 by thermal compression bonding. At this time, from the viewpoint of preventing bubbles from being enclosed, the temporary fixing material layer 42 having a film shape may be stacked under reduced pressure.

The material for the support 41 is not particularly limited as long as it has strength and stiffness at a level available to support the IC chip 10 and the passive components 21 and 22. For example, the support 41 may be a silicon wafer, a glass plate, or a stainless steel plate. The thickness of the support 41 is not particularly limited, and may be, for example, 200 to 2000 μm. An alignment mark for positioning an IC chip and a passive component may be provided on the surface of the support 41 on the side of the temporary fixing material layer 42. The alignment mark can be formed by using any materials such as a metal and a resin. The alignment mark may be engraved in the support 41 itself. In the case of providing an alignment mark, the temporary fixing material layer 42 may be transparent at a level available to visually recognize the alignment mark.

The temporary fixing material layer 42 has peelability at a level available to peel off the temporary fixing material layer 42 from the sealed structure 5. The thickness of the temporary fixing material layer 42 may be, for example, 1 to 400 μm. The material for forming the temporary fixing material layer 42 can be selected from materials used for temporary fixing or temporary bonding in the manufacturing of semiconductor devices (see, for example, Patent Literature 1). A commercially available protection tape for manufacturing a semiconductor may be used as the temporary fixing material layer.

FIG. 1(b) illustrates a process of disposing the IC chip 10 and the chip-type passive components 21 and 22 on the temporary fixing material layer 42. The order of disposing the IC chip 10 and the passive components 21 and 22 on the temporary fixing material layer 42 can be arbitrarily changed.

The IC chip 10 is usually a face-down type chip having a plurality of connection parts (pads) formed on one main surface side. The maximum width of the IC chip may be, for example, 100 to 50000 μm. The number of IC chips constituting one electronic component device may be one or two or more.

In the present embodiment, two types of the passive components 21 and 22 are disposed at predetermined positions around the IC chip 10. However, the number and the type of passive components constituting one electronic component device are not particularly limited, and are selected according to the design of the electronic component device. A passive component constituting one electronic component device may be, for example, a resistor, a capacitor, or a combination of these. The passive components 21 and 22 can be mounted on the temporary fixing material layer 42 by using a general chip mounting machine. The maximum width of the passive component may be 6500 μm or less and may be 50 μm or more. The passive components 21 and 22 have the main body parts 21a and 22a and the connection parts 21b and 22b for electrically connecting the passive components 21 and 22 to the wiring. The form (shape, thickness, and the like) of the connection parts 21b and 22b is not particularly limited, but the thickness of the connection parts 21b and 22b may be, for example, 5 to 30 μm. The thickness of the connection part may be regarded as the width G of the gap formed between the main body part of the passive component and the temporary fixing material layer. The distance between the IC chip and each passive component is not particularly limited, and may be, for example, 0.02 to 50 mm.

FIG. 1(c) illustrates a process of forming the sealing layer 1 sealing the IC chip 10 and the passive components 21 and 22 on the temporary fixing material layer 42. The sealing layer 1 is formed to entirely cover the IC chip 10 and the passive components 21 and 22 and, at the same time, to fill the gap between these electronic components and the temporary fixing material layer 42. However, the gap may not be completely filled.

The sealing layer 1 can be formed in a mold, for example, by compression molding or transfer molding using a curable sealing material. Molding conditions for forming a sealing layer can be adjusted in consideration of the viscosity, the reactivity, and the like of the sealing material. For example, the heating temperature for forming the sealing layer 1 may be 100° C. to 200° C.

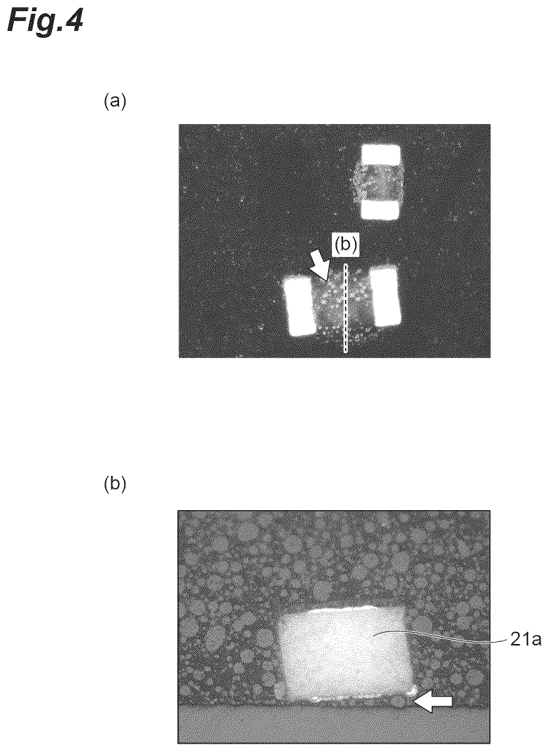

The curable sealing material contains a curable resin and a filler. According to findings of the present inventors, the degree of the movement (drift) of the passive component from a predetermined position in association with the formation of the sealing layer is likely to be affected by a filler having a particularly large particle diameter among fillers in the sealing material. FIG. 4 is a micrograph showing an example of a state where a passive component moves from a predetermined position. FIG. 4(a) is a micrograph obtained when a passive component having moved from a predetermined position in association with the formation of a sealing layer is observed from a surface of a sealed structure on which the passive component is exposed. FIG. 4(b) is a micrograph obtained when a passive component having moved from a predetermined position in association with the formation of a sealing layer is observed in the cross-section of an electronic component device after a redistribution layer is formed. The cross-section of FIG. 4(b) corresponds to the cross-section along the dashed line in FIG. 4(a). A filler having a relatively large particle diameter is observed at the position indicated by the arrow inserted in the photograph. It is conceivable that this filler having a relatively large particle diameter causes the movement of the passive component.

In this regard, by focusing on the top cut particle diameter and setting the relation between the top cut particle diameter and the width G of the gap in a specific range, the movement of the passive component can be suppressed. Specifically, assuming that the top cut particle diameter of the filler is designated as D and the width of the gap between the main body part of the passive component and the temporary fixing material layer is designated as G, when D/G is 1.5 or less, the movement of the passive component from a predetermined position is effectively suppressed. From the viewpoint of suppressing the movement of the passive component, D/G may be 1.4 or less, 1.3 or less, 1.2 or less, 1.1 or less, 1.0 or less, or 0.9 or less. The lower limit of D/G is not particularly limited, and D/G may be, for example, 0.1 or more, 0.2 or more, or 0.3 or more.

The top cut particle diameter D of the filler is a particle diameter (D₁₀₀) where the cumulative frequency in the particle size distribution of the filler becomes 100%, that is, the maximum particle diameter. The top cut particle diameter and the average particle diameter can be obtained from the volume-based particle size distribution as determined by a laser diffraction/scattering method.

The top cut particle diameter D of the filler may be 30 μm or less. In the case of using a typical chip-type passive component, even when the width G of the gap between the main body part of the passive component and the temporary fixing material layer is not necessarily considered, if the top cut particle diameter D is 30 μm or less, the movement of the passive component in association with the formation of the sealing layer can be suppressed. From the same viewpoint, the top cut particle diameter D of the filler may be 25 μm or less, 20 μm or less, or 15 μm or less, and may be 1 μm or more, 2 μm or more, or 3 μm or more. The average particle diameter of the filler may be 1 μm or more, and may be 20 μm or less, 15 μm or less, 10 μm or less, or 5 μm or less.

The degree of circularity of the filler may be, for example, 0.9 to 1. When the degree of circularity of the filler is within this range, effects that the degree of viscosity increase of the resin is small and the filler can be mixed in a large amount are obtainable. The degree of circularity of the filler is calculated from an area S and a boundary length L of a filler image as determined from an image of the cross-section of the sealing layer by formula: 4πS/L². An average value of the degrees of circularity of arbitrary ten or more fillers in the sealing material or the sealing layer may be within the above range.

The filler may be, for example, particles containing silica, alumina, zirconia, silicate calcium, calcium carbonate, potassium titanate, silicon carbide, silicon nitride, aluminum nitride, boron nitride, beryllia, forsterite, steatite, spinel, mullite, titania, or a combination of these, and may be glass fibers. The filler may be fused silica or crystalline silica, and may be fused silica.

The width G of the gap between the main body part of the passive component and the temporary fixing material layer is the width of a gap in a thickness direction of the temporary fixing material layer, and can be checked, for example, by cross-sectional observation. In a case where the width G of the gap between the temporary fixing material layer and one passive component or two or more passive components constituting the electronic component device fluctuates, D/G as determined by the minimum value among the fluctuating widths may be within the numerical range described above. In general, the width G of the gap between the main body part of the passive component and the temporary fixing material layer is substantially the same as the width of a gap formed between the main body part of the passive component and the redistribution layer after the redistribution layer is formed. The width G of the gap may be 10 μm or less.

The curable resin constituting the sealing material may be, for example, an epoxy resin, and in this case, the sealing material may further contain a curing agent for an epoxy resin.

The epoxy resin is not particularly limited, and may be selected from those which are generally used in a sealing material for a semiconductor device. Specific examples of the epoxy resin include novolac type epoxy resins such as a phenol novolac type epoxy resin, an orthocresol novolac type epoxy resin, and an epoxy resin having a triphenylmethane skeleton; bisphenol type epoxy resins that are diglycidyl ethers such as bisphenol A, bisphenol F, bisphenol S, and alkyl substituted or unsubstituted biphenol; stilbene type epoxy resins; hydroquinone type epoxy resins; glycidyl ester type epoxy resins; glycidyl amine type epoxy resins; epoxidized products of co-condensation resins of dicyclopentadiene with phenols; epoxy resins having a naphthalene ring; epoxidized products of aralkyl type phenolic resins such as a phenol aralkyl resin and a naphthol aralkyl resin; trimethylol propane type epoxy resins; terpene-modified epoxy resins; linear aliphatic epoxy resins obtained by oxidizing an olefin bond with a peroxy acid such as peracetic acid; alicyclic epoxy resins; and sulfur atom-containing epoxy resins.

The curing agent for an epoxy resin is not particularly limited, and specific examples thereof include novolac type phenolic resins, phenol aralkyl resins, aralkyl type phenolic resins, cyclopentadiene type phenol novolac resins, and terpene-modified phenolic resins.

The content of the filler in the sealing material or the sealing layer formed therefrom may be 55 to 90% by volume, 60 to 90% by volume, or 70 to 85% by volume, with respect to the volume of the sealing material or the sealing layer. When the content of the filler is 55% by volume or more, there is a tendency that reflow resistance is improved, and when the content of the filler is 90% by volume or more, there is a tendency that fillability is improved.

The sealing material may further contain a silane coupling agent. Examples of the silane coupling agent include a silane compound or titanium compound having an amino group, an epoxy group, a mercapto group, an alkyl group, a ureido group, or a vinyl group, aluminum chelate, and an aluminum/zirconium-based compound.

By curing the sealing layer 1 formed of the sealing material, the sealed structure 5 having the IC chip 10, the passive components 21 and 22, and the cured sealing layer 1 is formed. The sealing layer 1 can be cured by heating in a mold for compression molding, heating in an oven or the like after mold releasing, or both of these. The heating temperature for curing may be 100° C. to 200° C. The heating time for curing may be 1 to 24 hours.

When the carrier substrate 40 is peeled off from the sealed structure 5 of FIG. 2, generally, the IC chip 10 and the passive components 21 and 22 are exposed on one main surface of the sealed structure 5. The carrier substrate 40 can be peeled off from the sealed structure 5, for example, by mechanical peeling, which applies tensile stress or shear stress, heating, light irradiation, or a combination of these.

The redistribution layer 3 having the wiring 31 and the insulating layer 32 is formed on one main surface of the sealed structure 5 which is exposed by peeling off the carrier substrate 40. Thereby, an electronic component device 100 having the sealed structure 5 and the redistribution layer 3 is formed. The wirings 31 are electrically connected to the IC chip and the passive components via the connection parts. The insulating layer 32 is provided between the wirings 31. The wiring 31 includes a multi-layer portion extending in a direction parallel to a main surface of the redistribution layer 3 and a portion extending in a direction perpendicular to the main surface of the redistribution layer 3. The thickness of the wiring 31 at the portion extending in the direction parallel to the main surface of the redistribution layer 3 is not particularly limited, and may be, for example, 1 to 30 μm. The redistribution layer 3 can be formed by a general method which is known by those skilled in the art. The method for forming the redistribution layer can refer to, for example, Japanese Patent No. 5494766.

The IC chip and the passive component that constitute each of a plurality of electronic component devices may be disposed on the temporary fixing material layer of one sheet of the carrier substrate. In this case, the plurality of electronic component devices can be obtained by a step of dividing a laminate including the sealed structure 5 and the redistribution layer 3 into individual electronic component devices after the step of forming the redistribution layer.

### EXAMPLES

Hereinafter, test examples in which a test device having an IC chip, a passive component, and a sealing layer sealing these component parts was produced and a relation between the movement of the passive component in association with the formation of the sealing layer and the particle diameter of the filler was verified will be illustrated.

Carrier Substrate

ICROS Tape (trade name, manufactured by Mitsui Chemicals Tohcello, Inc., thickness 100 μm) was prepared as the temporary fixing material layer. The ICROS Tape was attached to the entire surface of a silicon wafer having a diameter of 300 mm to obtain a carrier substrate.

Temporary Fixing of IC Chip and Passive Component

IC chips and passive components corresponding to 144 electronic component devices (packages) were disposed at a predetermined position on the temporary fixing material layer (ICROS Tape) of the carrier substrate by using a mounter and 2 N of load was applied to temporarily fix these component parts to the temporary fixing material layer. Each electronic component device is configured by one IC chip (size: 7.3 mm×7.3 mm×0.4 mm thick) and four passive components (resistor, size: 0.6 mm×0.3 mm×0.22 mm thick) disposed around the IC chip.

Formation of Sealing Layer

Three types of sealing materials for a semiconductor containing an epoxy resin and a filler (silica particles) were prepared. The top cut and average particle diameters of the filler contained in each of the sealing materials are shown in Table 1. A sealing layer sealing the IC chips and the passive components was formed on the temporary fixing material layer by compression molding using these sealing materials. The sealing layer was formed by compression molding at a temperature of 140° C. for a pressing time of 20 seconds and the sealing layer was heated for 480 seconds. The sealed structure thus formed was heated in an oven at 140° C. for 5 hours to further cure the sealing layer.

The viscosity of each sealing material after being heated at 140° C. for 20 seconds was calculated by a method utilizing the Castro-Macosko model. The shearing rate was set to 1 to 10 [1/s].

Peeling-Off of Carrier Substrate

The ICROS Tape was heated to 200° C. to be foamed, the support 41 was removed, and then the ICROS Tape was rapidly peeled off from the sealed structure, so that the carrier substrate was peeled off from the sealed structure.

Checking of Drift of Passive Component

The surface of the sealed structure thus obtained on which the passive components and the IC chips were exposed was observed, and the positions of the passive components were measured by a laser displacement meter. The ratio (drift ratio) of passive components having moved from the predetermined position among all the passive components was obtained. Results are shown in Table 1.

Formation of Redistribution Layer

An insulating layer was formed using a photosensitive insulating resin (AH-3000 (trade name), manufactured by Hitachi Chemical Co., Ltd.) and a photosensitive film (RY-5110) and a wiring was formed by Cu plating, thereby forming a redistribution layer on the surface of the sealed structure on which the passive components and the IC chips were exposed. The cross-section of the structure thus obtained was observed, the width of the gap between the main body part of the passive component and the redistribution layer was obtained from the cross-sectional photograph, and this width was regarded as the width G of the gap between the main body part of the passive component and the temporary fixing material layer.

TABLE 1

| | Sealing material | | | | | |
|---|---|---|---|---|---|---|
| | Filler particle | | | Width G | | |
| | diameter [μm] | | Viscosity | [μm] | | Drift rate |
| Test | Top cut D | Average | [Pa · s] | of gap | D/G | [%] |
| 1 | 54 | 17 | 233-59 | 15 | 3.6 | 7.5 |
| 2 | 20 | 6 | 598-75 | 15 | 1.3 | 1.6 |
| 3 | 10 | 3 | 134-22 | 15 | 0.7 | 0.5 |

### REFERENCE SIGNS LIST

1: sealing layer, 3: redistribution layer, 5: sealed structure, 10: IC chip, 21, 22: passive component, 21a, 22a: main body part, 21b, 22b: connection part, 31: wiring, 32: insulating layer, 40: carrier substrate, 41: support, 42: temporary fixing material layer, 100: electronic component device, G: width of gap.

1. A method for manufacturing an electronic component device, the method comprising, in the stated order:
a step of preparing a carrier substrate comprising a support and a temporary fixing material layer provided on the support;
a step of disposing an IC chip and a chip-type passive component on the temporary fixing material layer, the passive component having a main body part and a connection part provided on an outer surface of the main body part, the connection part being interposed between the main body part and the temporary fixing material layer to form a gap between the main body part and the temporary fixing material layer;
a step of forming a sealing layer sealing the IC chip and the passive component on the temporary fixing material layer by a sealing material comprising a curable resin and a filler;
a step of curing the sealing layer to form a sealed structure having the IC chip, the passive component, and the cured sealing layer; and
a step of peeling off the carrier substrate from the sealed structure, wherein
when a top cut particle diameter of the filler is designated as D and a width of the gap between the main body part and the temporary fixing material layer is designated as G, D/G is 1.5 or less.

2. The method according to claim 1, wherein D is 30 μm or less.

3. The method according to claim 1, wherein G is 10 μm or less.

4. The method according to claim 1, wherein a maximum width of the passive component is 6500 μm or less.

5. The method according to claim 1, further comprising a step of forming a redistribution layer having a wiring connected to the IC chip and the connection part on one main surface side of the sealed structure after the step of peeling off the carrier substrate from the sealed structure.

6. The method according to claim 5, wherein the IC chip and the passive component that constitute each of a plurality of electronic component devices are disposed on the temporary fixing material layer of one sheet of the carrier substrate, and
the method further comprises a step of dividing the sealed structure and the redistribution layer into individual electronic component devices after the step of forming the redistribution layer.

7. An electronic component device comprising:
a sealed structure having an IC chip, a chip-type passive component, and a sealing layer sealing the IC chip and the passive component; and
a redistribution layer provided on one main surface side of the sealed structure, wherein
the passive component has a main body part and a connection part provided on an outer surface of the main body part, and the redistribution layer has a wiring connected to the connection part,
the connection part is interposed between the main body part and the redistribution layer to form a gap between the main body part and the redistribution layer,
the sealing layer is a cured product of a sealing material containing a curable resin and a filler, and
when a top cut particle diameter of a particle diameter of the filler is designated as D and a width of the gap between the main body part and the redistribution layer is designated as G, D/G is 1.5 or less.

8. The electronic component device according to claim 7, wherein D is 30 μm or less.

9. The electronic component device according to claim 7, wherein G is 10 μm or less.

10. The electronic component device according to claim 7, wherein a maximum width of the passive component is 6500 μm or less.
